(19) United States
(12) Patent Application Publication
(10) Pub. No.: US 2014/0292143 A1
(43) Pub. Date: Oct. 2, 2014

(54) ELECTRONIC DEVICE AND METHOD FOR FABRICATING THE SAME

(71) Applicant: NIHON DEMPA KOGYO CO., LTD., Tokyo (JP)

(72) Inventor: Ryoichi Ichikawa, Saitama (JP)

(73) Assignee: NIHON DEMPA KOGYO CO., LTD., Tokyo (JP)

(21) Appl. No.: 14/217,503

(22) Filed: Mar. 18, 2014

(30) Foreign Application Priority Data
Mar. 29, 2013 (JP) 2013-072623

(51) Int. Cl. H01L 41/053

(52) U.S. Cl. CPC H01L 41/053
USPC 310/311

(57) ABSTRACT

The disclosure provides an electronic device that includes a substrate and a lid. The lid is bonded on the substrate to seal an inside of the lid using a resin. The lid includes a contact surface in contact with the resin. The contact surface includes a rough surface with an uneven shape.

### CROSS REFERENCE TO RELATED APPLICATIONS

This application claims the priority benefit of Japan application serial no. 2013-072623, filed on Mar. 29, 2013. The entirety of the above-mentioned patent application is hereby incorporated by reference herein and made a part of this specification.

### TECHNICAL FIELD

This disclosure relates to an electronic device and a method for fabricating the electronic device. In particular, this disclosure relates to an electronic device that allows forming a resin for bonding a lid and a base to be in a good fillet shape to improve moisture proof property and a method for fabricating the electronic device.

### DESCRIPTION OF THE RELATED ART

### Related Art

As a conventional electronic device, there is a crystal unit for surface mounting or a similar unit. A conventional crystal unit will be described with reference to FIG. 4A to FIG. 4C. FIG. 4A to FIG. 4C are cross-sectional explanatory views of a conventional crystal unit. In the conventional crystal unit, a metal or a ceramic lid illustrated in FIG. 4A, which is a lid 1, is mounted on a substrate 3 via resin 4 as illustrated in FIG. 4B. The substrate 3 is formed of a ceramic base or a similar base and provided with a crystal element 5 secured with a conductive adhesive 6. As illustrated in FIG. 4C, the lid 1 is pressed to the substrate 3 to expand the resin 4, thus the crystal element 5 is airtightly sealed with resin.

Configuration without Fillet: FIG. 5

As long as the resin 4 is pressed and expanded with a contact surface of the lid 1 and stuck out from the contact surface (a configuration with a fillet, a configuration where a fillet shape is formed), water vapor is less likely to percolate into the lid 1. However, as illustrated in FIG. 5, if the resin 4 is not expanded to the outside of the lid 1 (a configuration without a fillet), water vapor is likely to percolate. This may deteriorate moisture proof property. FIG. 5 is a cross-sectional cross-sectional explanatory view illustrating a configuration without a fillet.

As a pertaining prior art, there are Japanese Patent No. 3183065 “ METHOD FOR FABRICATING PIEZOELECTRIC COMPONENT” (Murata Manufacturing Co., Ltd.) [Patent Literature 1], International Publication Number WO 2010/074127 “PIEZOELECTRIC VIBRATING DEVICE, METHOD FOR FABRICATING THE SAME, AND ETCHING METHOD FOR STRUCTURAL COMPONENTS CONSTITUTING THE SAME” (Daishinku Corp.) [Patent Literature 2], Japanese Unexamined Patent Application Publication No. 2012-74837 “PIEZOELECTRIC DEVICE” (NIHON DEMPA KOGYO CO., LTD.) [Patent Literature 3], and Japanese Unexamined Patent Application Publication No. 2003-264447 “PIEZOELECTRIC RESONATOR AND METHOD FOR FABRICATING THE SAME” (Seiko Instruments Inc.) [Patent Literature 4].

Patent Literature 1 discloses the following. An inner surface side of an opening of a cap made of metal is inclined to an outer surface side. An adhesive is applied over the opening for sealing with resin. Patent Literature 2 discloses the following. Surface roughening is performed on a lid. The lid is bonded to a crystal vibrating plate with a metal bonding material.

Patent Literature 3 discloses the following. Surface roughening is performed on a lid, and a metal film is formed on the lid. The lid is bonded to a base portion with a low-melting-point glass. Patent Literature 4 discloses the following. A bonding film formed by bonding a blank and a lid body together via a metal film is coated with fluoroplastic and a fluorine compound.

As described above, in the conventional electronic devices, the resin is uncovered at the bonding surface between the lid and the substrate. In particular, for the electronic device without a fillet, the resin does not fully cover the bonding portion between the lid and the substrate. This deteriorates the moisture proof property, causing a problem of variation in quality.

Patent Literatures 1 to 4 do not disclose that surface roughening is performed on a lid of an electronic device with a lid and a substrate bonded together with resin so as to easily form a fillet.

A need thus exists for an electronic device and a method for fabricating the electronic device which are not susceptible to the drawbacks mentioned above.

### SUMMARY

According to an aspect of this disclosure, an electronic device includes a substrate and a lid. The lid is bonded on the substrate to seal an inside of the lid using a resin. The lid includes a contact surface in contact with the resin. The contact surface includes a rough surface with an uneven shape.

### BRIEF DESCRIPTION OF THE DRAWINGS

The foregoing and additional features and characteristics of this disclosure will become more apparent from the following detailed description considered with reference to the accompanying drawings, wherein:

FIG. 1A to FIG. 1C are cross-sectional explanatory views of a first crystal unit according to the disclosure.

FIG. 2 is a cross-sectional explanatory view illustrating a configuration of a protective film formed on the first crystal unit.

FIG. 3A to FIG. 3C are cross-sectional explanatory views of a second crystal unit according to the disclosure.

FIG. 4A to FIG. 4C are cross-sectional explanatory views of a conventional crystal unit.

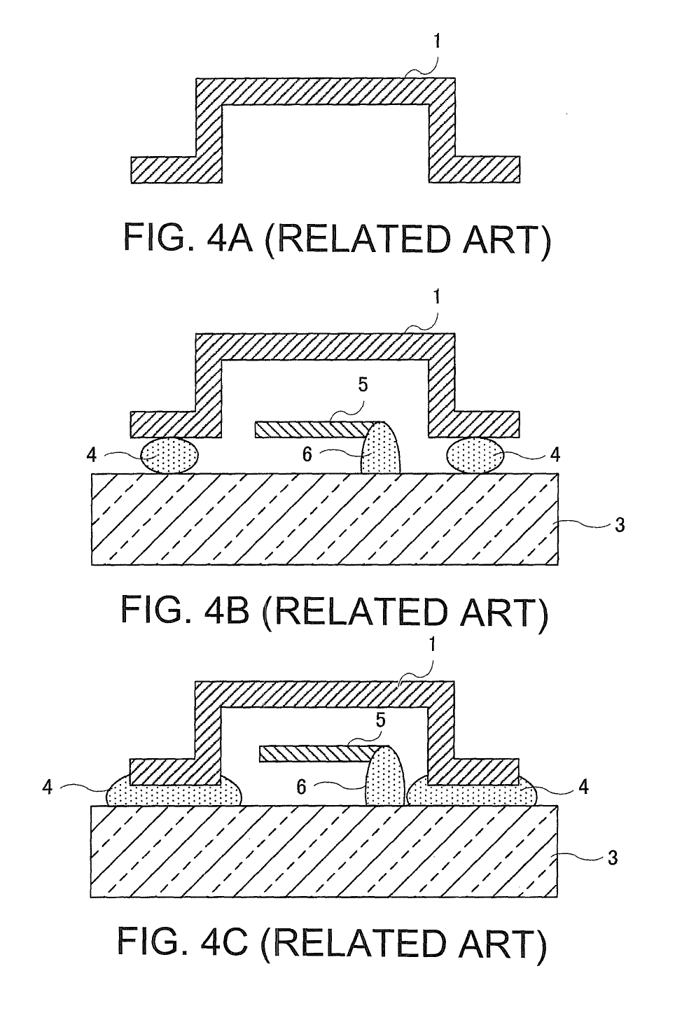

FIG. 5 is a cross-sectional explanatory view illustrating a configuration without a fillet.

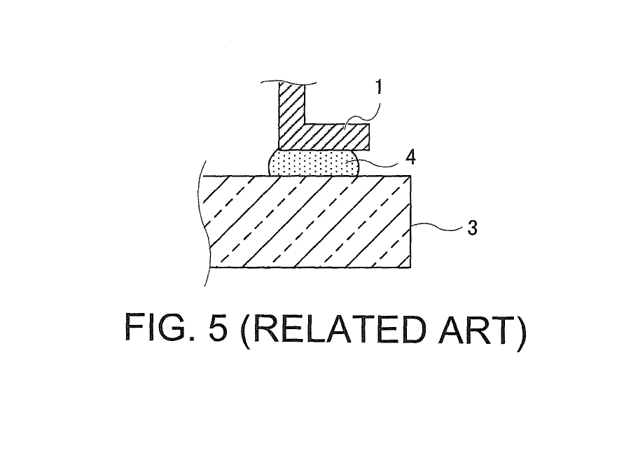

### DETAILED DESCRIPTION

### Outline of Embodiments

Embodiments of this disclosure will be explained with reference to the attached drawings. An electronic device according to the embodiments of this disclosure includes a base and a lid. The lid is bonded on the base with resin to seal the inside of the lid. A contact surface to be in contact with the resin at the lid is formed as an uneven rough surface to cause the resin to easily expand and easily form a fillet. This improves adhesiveness between the resin and the lid, improves water resistance, and improves the quality of the electronic device.

The electronic device according to the embodiment of this disclosure forms a water-repellent thin film at the contact surface in contact with the resin at the lid to easily repel the resin to the outside. This facilitates the formation of the fillet, improves water resistance, and improves the quality of the electronic device.

As the electronic device, the following describes with an example of a crystal unit for surface mounting. However, this disclosure is applicable to the electronic device as long as the electronic device has a configuration where a lid is bonded to a base with resin and seals the inside of the lid.

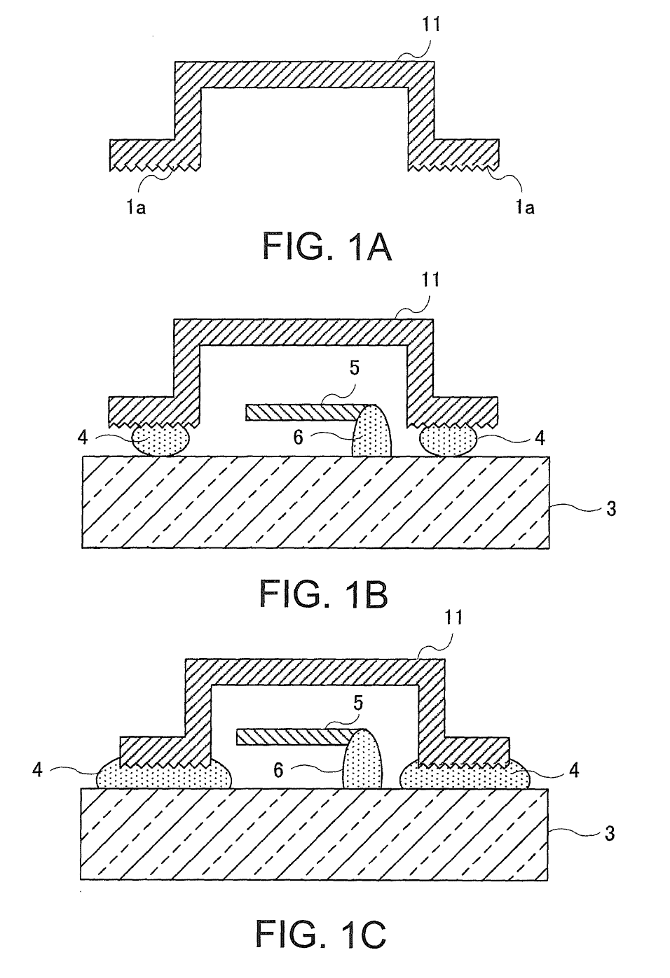

### First Crystal Unit: FIG. 1A to FIG. 1C

A description will be given of a first crystal unit (the first crystal unit) according to the embodiment of this disclosure with reference to FIG. 1A to FIG. 1C. FIG. 1A to FIG. 1C are cross-sectional explanatory views of the first crystal unit. FIG. 1A illustrates a lid 11 for the first crystal unit. The lid 11 is mounted on a base with its U-shape inverted. The lid 11 includes a contact surface 1a to be in contact with resin, which is a sealing agent.

In the first crystal unit, the contact surface 1a to be in contact with the resin at the lid 11 is formed as a rough surface with a fine concavo-convex shape. Surface roughening to form the contact surface 1a as a rough surface is performed by Ar (Argon) plasma treatment. By forming the contact surface 1a to be in contact with the resin as a rough surface with appropriate unevenness, wettability of the resin becomes good, causing the resin to easily expand in pressing the lid 11 on the substrate 3. Roughness Ra of the rough surface is approximately 10000 angstroms. Here, this example shows surface roughening of only the contact surface 1a. However, surface roughening may be performed on the entire inside of the lid 11 (the depressed portion side) to form a rough surface.

FIG. 1B illustrates a state where the lid 11 is mounted on the substrate 3 via resin 4. The substrate 3 is formed of a ceramic base or a similar base and provided with the crystal element 5 secured with the conductive adhesive 6. The lid 11 includes the contact surface 1a on which surface roughening is performed. As the resin 4, epoxy resin or a similar material is employed.

FIG. 1C illustrates a state where the lid 11 is pressed to the substrate 3 to seal the inside of the lid 11 with resin. A part where the lid 11 is bonded on the substrate 3 with the resin 4 forms a sealing portion. In the first crystal unit, surface roughening is performed on the contact surface 1 a in contact with the resin 4 at the lid 11. Accordingly, the resin 4 easily expands and expands to the outside of the lid 11 by the rough surface, easily forming a state with a fillet.

Accordingly, the first crystal unit fully covers a bonding portion between the substrate 3 and the lid 11, which is the sealing portion, with the fillet of the resin 4, thus improving the moisture proof property. Further, the surface roughening allows enlarging a contacted area between the resin 4 and the lid 11, improving adhesiveness between the resin 4 and the lid 11. The first crystal unit requires only surface roughening of the contact surface to be in contact with the resin. This achieves a crystal unit with a sufficient fillet and excellent moisture proof property at a low cost.

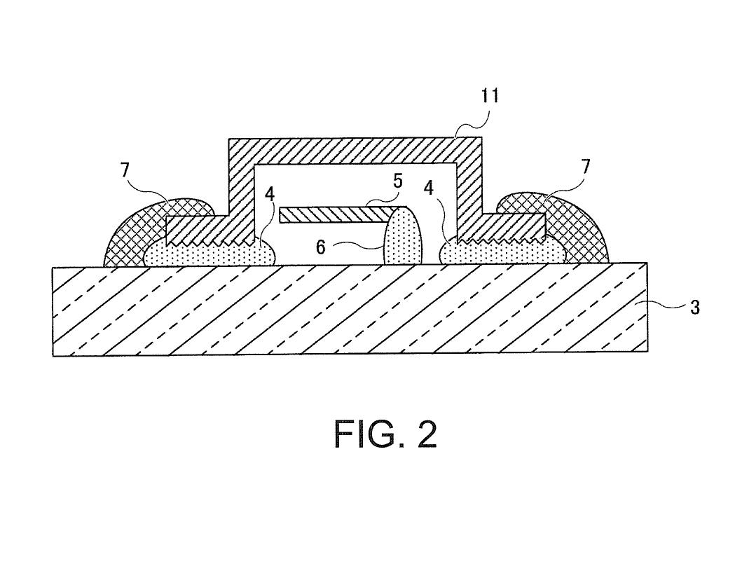

Configuration with Protective Film: FIG. 2

Next, a configuration of forming a protective film at the first crystal unit is described with reference to FIG. 2. FIG. 2 is a cross-sectional explanatory view illustrating a configuration of a protective film formed on the first crystal unit. FIG. 2 illustrates a configuration where a protective film 7 is formed in a state illustrated in FIG. 1C so as to cover the sealing portion.

As the protective film 7, a silicon oxide film (SiO₂: silicon dioxide), a silicon nitride film (Si₃N₄), or a similar film is employed for improving water repellency property. Here, in the first crystal unit, the resin 4 can be formed in a good fillet shape. This ensures forming the protective film 7 so as not to form a gap between the protective film 7 and the resin 4 in formation of the protective film 7, improves adhesiveness, and further improves the moisture proof property of the crystal unit.

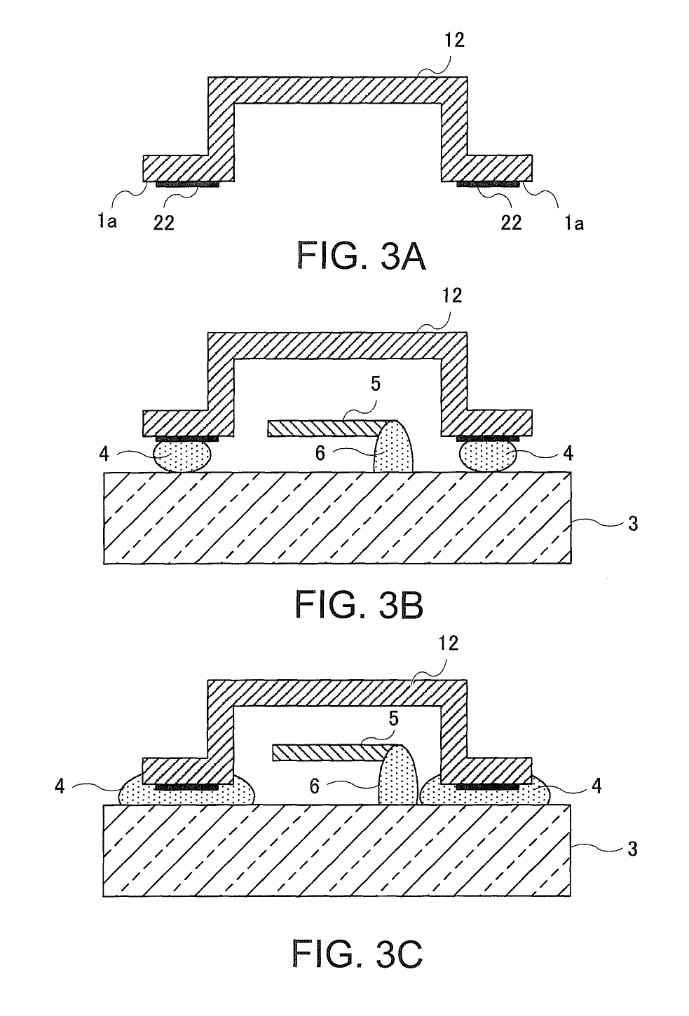

### Second Crystal Unit: FIG. 3A to FIG. 3C

Next, a description will be given of a second crystal unit (the second crystal unit) according to the embodiment of this disclosure with reference to FIG. 3A to FIG. 3C. FIG. 3A to FIG. 3C are cross-sectional explanatory views of the second crystal unit. FIG. 3A illustrates a lid 12 for the second crystal unit. The lid 12 includes a water-repellent thin film 22 at the contact surface 1a to be in contact with the resin. The water-repellent thin film 22 includes: a thin film for which fluorine-based hydrophobic liquid is attached and hardened and a thin film formed by sputtering a thin film of a silicon oxide film (SiO₂) or a similar method.

The second crystal unit includes the water-repellent thin film 22 near the center of the contact surface 1a. Resin is repelled at the part, thus the resin is easily pressed and expanded to the outside. The water-repellent thin film 22 is not formed at the outer periphery part of the contact surface 1a. This leaves adhesiveness between the lid 12 and the resin 4 intact.

FIG. 3B illustrates a state where the lid 12 is mounted on the substrate 3. FIG. 3C illustrates a state where the lid 12 is pressed to the substrate 3, the resin is expanded, and the inside of the lid 12 is sealed. The second crystal unit includes the water-repellent thin film 22 at the center of the contact surface la in contact with the resin 4 at the lid 12. This repels the resin 4 and easily expands the resin 4 to the outside. Then, the resin 4 expands to the outside of the lid 12, easily forming a state with a fillet.

In particular, in formation of the water-repellent thin film 22 with hydrophobic liquid, a good fillet shape can be obtained with a fabrication process easier than the fabrication process for the first crystal unit. Thus, a crystal unit with excellent moisture proof property can be easily achieved. Further, in the second crystal unit as well, forming the protective film at the sealing portion allows further improving the moisture proof property.

### Effects of Embodiments

According to the first crystal unit, surface roughening is performed on the contact surface to be in contact with the resin 4 at the lid 11 to form a rough surface with a fine concavo-convex shape. This rough surface allows easily expanding the resin 4 and easily forming the resin 4 to have a fillet shape, thus ensuring an effect of improving moisture proof property.

According to the second crystal unit, the water-repellent thin film 22 made of a fluorine-based water-repellent agent or silicon dioxide is formed at a contact surface to be in contact with the resin 4 at the lid 12. The resin 4 is repelled by the water-repellent thin film 22, thus facilitating the resin 4 to expand to the outside. This water-repellent thin film 22 allows easily forming the resin 4 to be in a fillet shape, thus ensuring the improved effect of the moisture proof property.

Further, the water-repellent protective film 7 is formed at the first and the second crystal units to cover the sealing portion. The sealing portion is a part where the lid 11 or 12 and the substrate 3 are bonded together with the resin 4. This has effects of forming the protective film 7 on the good fillet shape, enhancing adhesiveness between the protective film 7 and the resin 4, reliably protecting the entire sealing portion, and further improving the moisture proof property.

This disclosure is preferable for an electronic device and a method for fabricating the electronic device that can form resin for bonding a lid and a base to have a good fillet shape to improve moisture proof property.

The disclosure for solving the conventional problems provides an electronic device where a lid is bonded on a substrate using a resin and an inside of the lid is sealed. The lid includes a contact surface in contact with the resin. The contact surface includes a water-repellent thin film.

In the above-described electronic device, the disclosure is configured as follows. The thin film is formed of a fluorine-based water-repellent agent or silicon dioxide.

In the above-described electronic device, the disclosure is configured as follows. A part where a lid is bonded on a substrate using the resin forms a sealing portion. A protective film is formed so as to cover the sealing portion.

The disclosure for solving the conventional problems provides a method for fabricating an electronic device that bonds a lid to a substrate using a resin. The method for fabricating an electronic device seals an inside of the lid. The method for fabricating an electronic device includes: forming a contact surface to be in contact with the resin at the lid as a rough surface with a concavo-convex shape and pressing a lid where the rough surface is formed to the substrate via the resin for sealing.

In the above-described method for fabricating an electronic device, the disclosure is configured as follows. The rough surface is filmed by argon plasma treatment.

The disclosure for solving the conventional problems provides a method for fabricating an electronic device that bonds a lid to a substrate using a resin. The method for fabricating an electronic device seals an inside of the lid. The method for fabricating an electronic device includes: forming a thin film made of a fluorine-based water-repellent agent or silicon dioxide at a contact surface to be in contact with the resin at the lid and pressing the lid where the thin film is formed to the substrate via the resin for sealing.

According to the embodiment, the electronic device where the lid is bonded on the substrate with the resin and the inside of the lid is sealed is formed. The lid includes a contact surface to be in contact with the resin. The contact surface is formed as a rough surface with a concavo-convex shape. This causes the resin to easily expand and being formed to have a good fillet shape. This has effects of improving adhesiveness between the resin and the lid, improving moisture proof property, and improving the quality of the electronic device.

According to the embodiment, the electronic device where the lid is bonded on the substrate with the resin and the inside of the lid is sealed. The lid includes a contact surface to be in contact with the resin. The contact surface includes a water-repellent thin film. This has effects of pressing and expanding the resin to the outside at the contact surface in contact with the resin, forming the resin to have a good fillet shape, improving the moisture proof property, and improving the quality of the electronic device.

According to the embodiment, the above-described electronic device is configured as follows. The part where the lid is bonded on the substrate with resin forms a sealing portion. A protective film is formed so as to cover the sealing portion. Accordingly, the protective film is formed on the fillet formed to have a good shape. This has effects of preventing a gap between the resin and the protective film, ensuring good adhesiveness, reliably protecting the sealing portion, and further improving the moisture proof property.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. An electronic device, comprising:
a substrate; and
a lid, being bonded on the substrate to seal an inside of the lid using a resin,
wherein the lid includes a contact surface in contact with the resin, the contact surface including a rough surface with an uneven shape.

2. An electronic device, comprising:
a substrate; and
a lid, being bonded on the substrate to seal an inside of the lid using a resin,
wherein the lid includes a contact surface in contact with the resin, the contact surface including a water-repellent thin film.

3. The electronic device according to claim 2, wherein
the water-repellent thin film is formed of a fluorine-based water-repellent agent or silicon dioxide.

4. The electronic device according to claim 1, wherein
a part where the lid is bonded on the substrate using the resin forms a sealing portion, wherein
the electronic device further comprises a protective film formed so as to cover the sealing portion.

5. A method for fabricating an electronic device according to claim 1, comprising:
bonding a lid to a substrate using a resin to seal an inside of the lid, wherein the method includes:
forming a contact surface to be in contact with the resin at the lid as a rough surface with an uneven shape, and
pressing the lid with the rough surface on the substrate via the resin for sealing.

6. The method for fabricating an electronic device according to claim 5, wherein
the rough surface is formed by argon plasma treatment.

7. A method for fabricating an electronic device according to claim 2, comprising:
bonding a lid to a substrate using a resin to seal an inside of the lid, wherein the method includes:
forming a thin film made of a fluorine-based water-repellent agent or silicon dioxide at a contact surface to be in contact with the resin at the lid, and
pressing the lid with the thin film on the substrate via the resin for sealing.
